(19) United States
(12) Patent Application Publication
(10) Pub. No.: US 2014/0284678 A1
(43) Pub. Date: Sep. 25, 2014

(54) NON-VOLATILE MEMORY AND MANUFACTURING METHOD THEREOF

(71) Applicant: Powerchip Technology Corporation, Hsinchu (TW)

(72) Inventors: Hui-Huang Chen, Hsinchu City (TW); Chih-Yuan Chen, Hsinchu City (TW); Zih-Song Wang, Taoyuan County (TW)

(21) Appl. No.: 13/922,260

(22) Filed: Jun. 20, 2013

(30) Foreign Application Priority Data
Mar. 19, 2013 (TW) 102109666

(51) Int. Cl. H01L 29/788; H01L 29/66

(52) U.S. Cl. CPC H01L 29/788; H01L 29/66825
USPC 257/315; 438/264

(57) ABSTRACT

A non-volatile memory and a manufacturing method thereof are provided. The non-volatile memory includes a substrate, word lines, select lines, and doped regions. The substrate includes a memory cell region and two select line regions located at two opposite sides of the memory cell region. The word lines are disposed in the memory cell region. The select lines are disposed in the select line regions. A line width of each of the word lines is equal to a line width of each of the select lines. A distance between the adjacent word lines, a distance between the adjacent select lines, and a distance between the adjacent select line and word line are equal to one another. The doped regions are located in the substrate at two sides of each of the word lines and at two sides of each of the select line regions.

### CROSS-REFERENCE TO RELATED APPLICATION

This application claims the priority benefit of Taiwan application serial no. 102109666, filed on Mar. 19, 2013. The entirety of the above-mentioned patent application is hereby incorporated by reference herein and made a part of this specification.

### BACKGROUND OF THE INVENTION

1. Field of the Invention

The invention relates to a semiconductor device and a manufacturing method thereof and more particularly relates to a non-volatile memory and a manufacturing method thereof.

2. Description of Related Art

Non-volatile memory is a memory device that has been extensively used inside personal computers and electronic equipment because non-volatile memory can perform data storage, reading, and erasing, etc. many times and has the advantage of retaining the stored data even after power supply is cut off.

In the typical non-volatile memory, several memory cells are disposed in the memory cell region, and the gate structures of the memory cells in the same row are connected in series to form a word line. In addition, select line regions are disposed at two opposite sides of the memory cell region. The memory cell region has the word lines therein and the select line regions have select lines therein.

Generally the line width of the select line is greater than the line width of the word line. Therefore, when a mask is used to define the pattern of the word lines and the select lines during the fabrication, it becomes more difficult to design the mask and control the optical proximity effect. And, optical proximity correction (OPC) needs to be carried out many times to achieve accurate pattern line widths and pattern gaps.

### SUMMARY OF THE INVENTION

The invention provides a non-volatile memory, wherein a line width of a select line is the same as a line width of a word line; and a distance between adjacent word lines, a distance between adjacent select lines, and a distance between adjacent select line and word line are equal to one another.

The invention provides a manufacturing method of a non-volatile memory, which obtains an accurate pattern line width and an accurate pattern gap without performing an optical proximity correction several times.

The invention provides a manufacturing method of a non-volatile memory. The manufacturing method includes providing a substrate first, wherein the substrate includes a memory cell region and two select line regions. The select line regions are respectively disposed on two opposite sides of the memory cell region. Then, a first dielectric layer, a charge storage layer, and a second dielectric layer are formed on the substrate in sequence. Next, at least the second dielectric layer in the select line regions is removed. Thereafter, a conductor layer is formed on the substrate. Following that, a patterning process is performed to pattern the first dielectric layer, the charge storage layer, the second dielectric layer, and the conductor layer, so as to define a plurality of word lines in the memory cell region and define a plurality of select lines in the select line regions. A line width of each of the word lines is equal to a line width of each of the select lines. A distance between the adjacent word lines, a distance between the adjacent select lines, and a distance between the adjacent select line and word line are equal to one another. Then, a plurality of doped regions are formed in the substrate at two sides of each of the word lines and at two sides of each of the select line regions.

According to the manufacturing method of the non-volatile memory in an embodiment of the invention, the patterning process is a double patterning process, for example.

According to the manufacturing method of the non-volatile memory in an embodiment of the invention, the step of at least removing the second dielectric layer in the select line regions includes removing the second dielectric layer and a portion of the charge storage layer in the select line regions.

According to the manufacturing method of the non-volatile memory in an embodiment of the invention, the step of at least removing the second dielectric layer in the select line regions includes removing the second dielectric layer and the charge storage layer in the select line regions.

According to the manufacturing method of the non-volatile memory in an embodiment of the invention, wherein the substrate further includes a source region and a drain region, which are respectively adjacent to the corresponding select line regions.

The manufacturing method of the non-volatile memory in an embodiment of the invention further includes forming at least one stack structure respectively in the source region and the drain region when the patterning process is performed, wherein a line width of each stack structure is equal to the line width of each of the word lines. Then, the stack structure is removed.

The manufacturing method of the non-volatile memory in an embodiment of the invention further includes forming the doped regions in the source region and the drain region after the patterning process. Then, at least one source line contact is formed in the source region and at least one bit line contact is formed in the drain region. The doped regions are located in the substrate under and at two sides of each source line contact, and the source line contact is connected with the doped region in the source region. The doped regions are located in the substrate under and at two sides of each bit line contact, and the bit line contact is connected with the doped region in the drain region.

The manufacturing method of the non-volatile memory in an embodiment of the invention further includes defining at least one first stack structure that is stripe-shaped in the source region when the patterning process is performed. A line width of each first stack structure is equal to the line width of each of the word lines. A distance between the adjacent first stack structures, a distance between the adjacent first stack structure and select line, and a distance between the adjacent select lines are equal to one another.

The manufacturing method of the non-volatile memory in an embodiment of the invention further includes defining at least one stack structure in the drain region when the first stack structure is defined, wherein a line width of each stack structure is equal to the line width of each of the word lines. Then, the stack structure is removed.

The manufacturing method of the non-volatile memory in an embodiment of the invention further includes forming the doped region in the substrate at two sides of each first stack structure and forming the doped region in the drain region. Then, at least one bit line contact is formed in the drain region and the doped region is located in the substrate under and at two sides of each bit line contact, and the bit line contact is connected with the doped region in the drain region.

According to the manufacturing method of the non-volatile memory in an embodiment of the invention, the charge storage layer is a conductor layer or a nitride layer, for example.

The invention further provides a non-volatile memory, including a substrate, a plurality of word lines, a plurality of select lines, and a plurality of doped regions. The substrate includes a memory cell region and two select line regions respectively located at two opposite sides of the memory cell region. The word lines are disposed in the memory cell region. The select lines are disposed in the select line regions. A line width of each of the word lines is equal to a line width of each of the select lines. A distance between the adjacent word lines, a distance between the adjacent select lines, and a distance between the adjacent select line and word line are equal to one another. The doped regions are located in the substrate at two sides of each of the word lines and at two sides of each of the select line regions.

According to the non-volatile memory in an embodiment of the invention, the substrate further includes a source region and a drain region, wherein the source region is adjacent to one of the select line regions and located at a side of this select line region that is away from the memory cell region, the drain region is adjacent to the other select line region and located at a side of this select line region that is away from the memory cell region, and the doped regions further are located in the source region and the drain region.

The non-volatile memory in an embodiment of the invention further includes at least one source line contact located in the source region and at least one bit line contact located in the drain region. The doped region is located in the substrate under and at two sides of each source line contact, and the source line contact is connected with the doped region in the source region. The doped region is located in the substrate under and at two sides of each bit line contact, and the bit line contact is connected with the doped region in the drain region.

The non-volatile memory in an embodiment of the invention further includes at least one stripe-shaped first stack structure located in the source region and at least one bit line contact located in the drain region, wherein the doped region is located in the substrate at two sides of each first stack structure and the doped region is located in the substrate under and at two sides of each bit line contact, and the bit line contact is connected with the doped region in the drain region.

According to the non-volatile memory in an embodiment of the invention, a line width of each first stack structure is equal to a line width of each of the word lines.

According to the non-volatile memory in an embodiment of the invention, a distance between the adjacent first stack structures, a distance between the adjacent first stack structure and select line, and a distance between the adjacent select lines are equal to one another.

According to the non-volatile memory in an embodiment of the invention, the select lines are connected with each other in parallel.

Based on the above, in the non-volatile memory of the invention, the select lines and the word lines have the same line width. In addition, the distances between the adjacent word lines, the adjacent select lines, and the adjacent select line and word line are equal to one another. That is, the pattern of the select lines and the word lines is highly uniform in density. Accordingly, the design of the mask for defining the patterns is simplified, and fabrication difficulty and costs are both reduced. Moreover, accurate patterns can be easily formed.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIGS. 1A to 1F are schematic cross-sectional views illustrating a process of manufacturing a non-volatile memory according to an embodiment of the invention.

FIGS. 2A to 2B are schematic cross-sectional views illustrating a process of manufacturing a non-volatile memory according to an embodiment of the invention.

FIG. 3 illustrates an operation state when the select lines of the non-volatile memory in Example 1 of the invention are non-equipotential.

FIG. 4 illustrates an operation state when the select lines of the non-volatile memory in Example 1 of the invention are equipotential.

### DESCRIPTION OF THE EMBODIMENTS

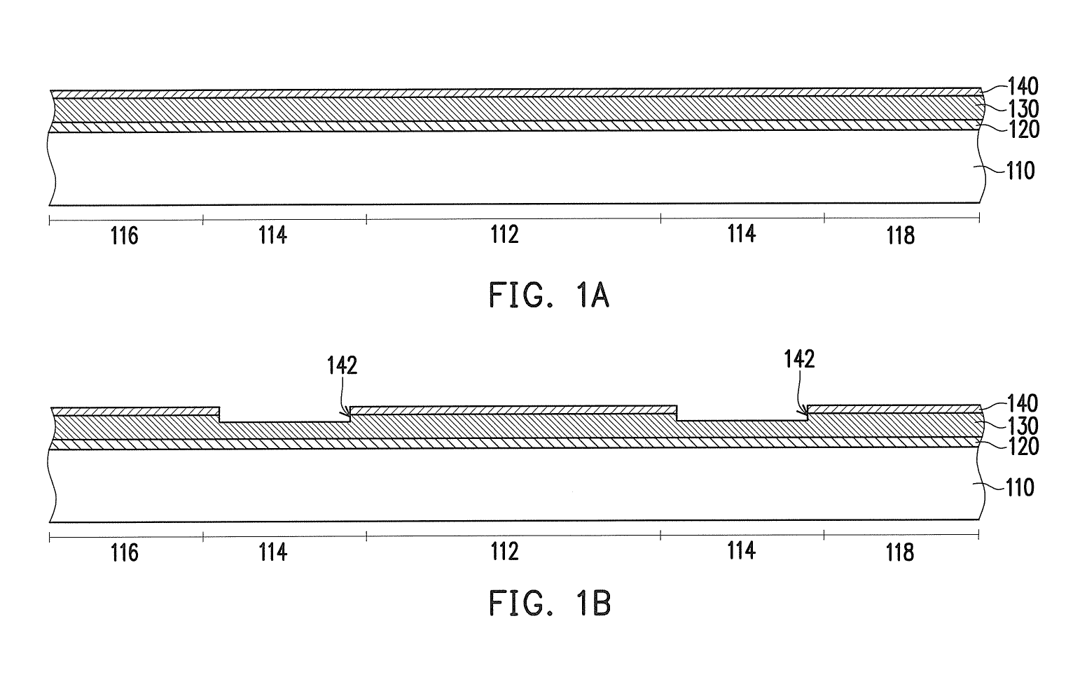

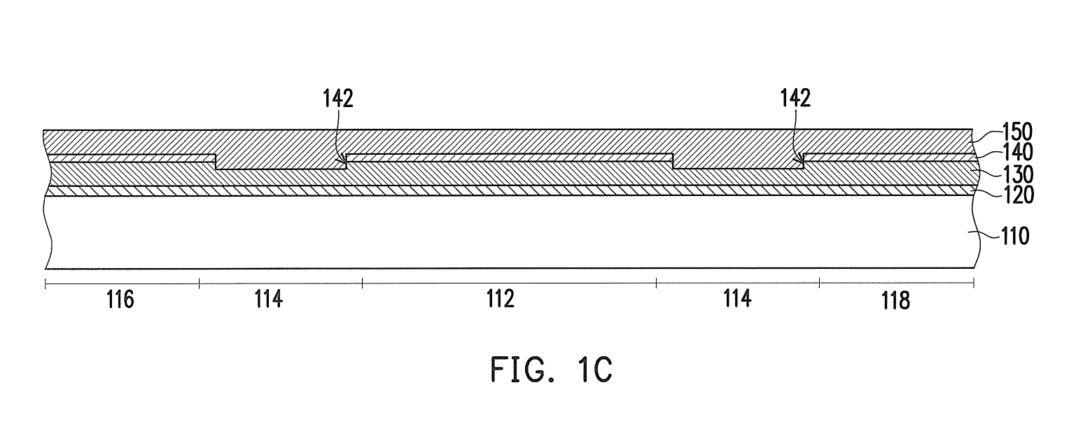

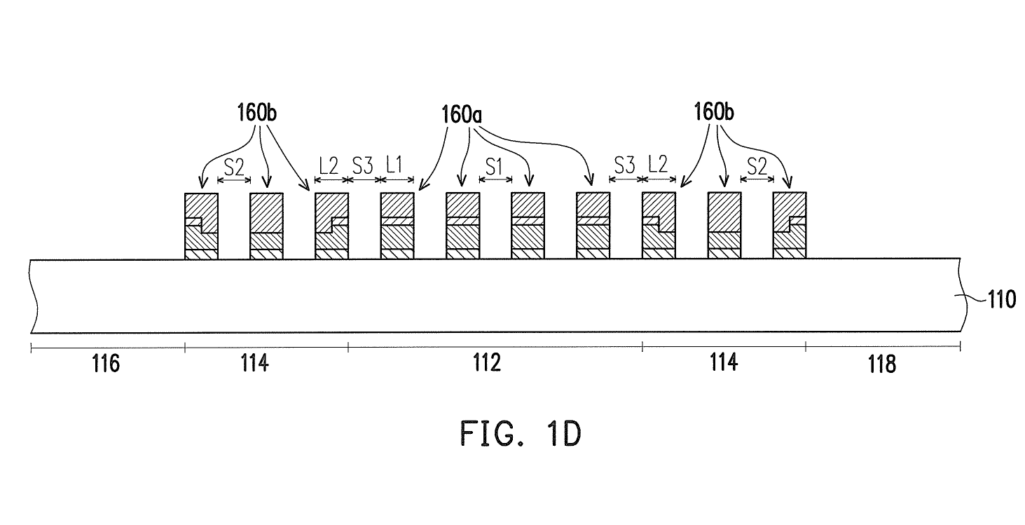

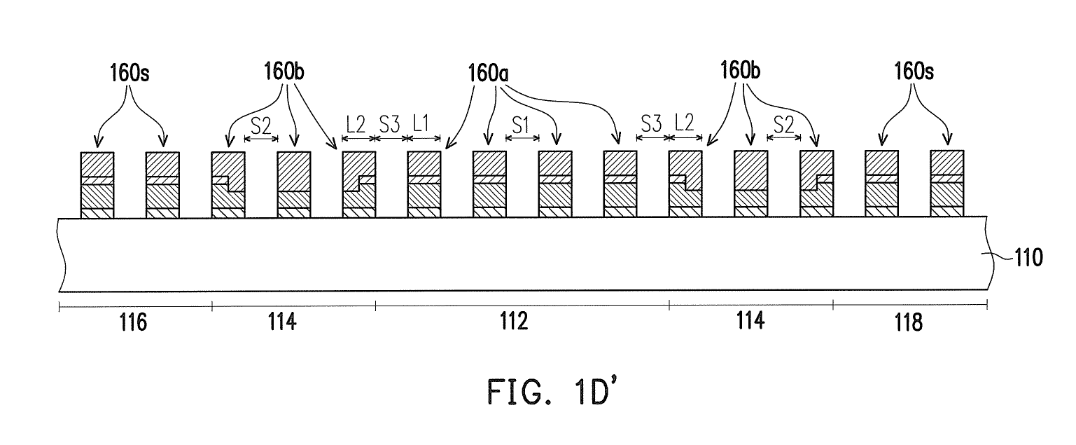

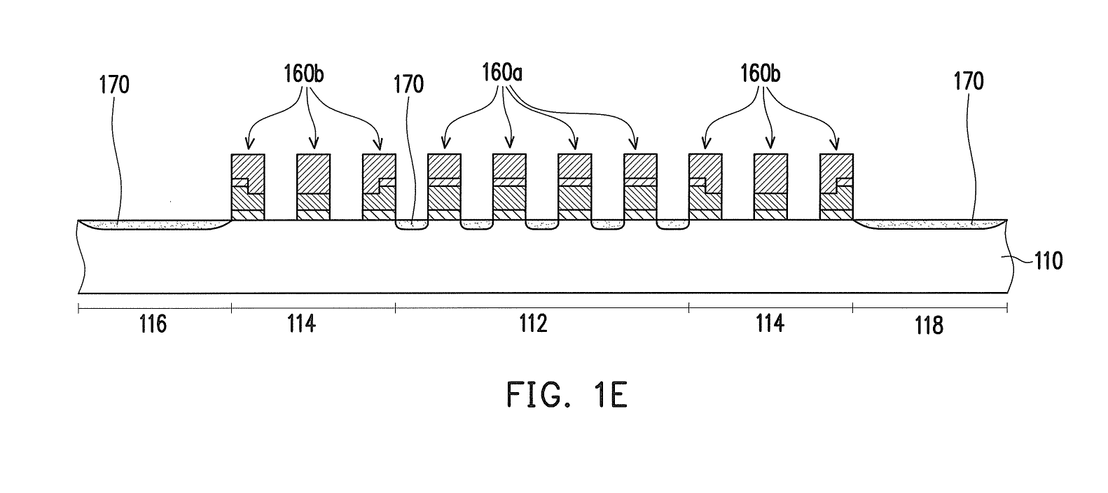

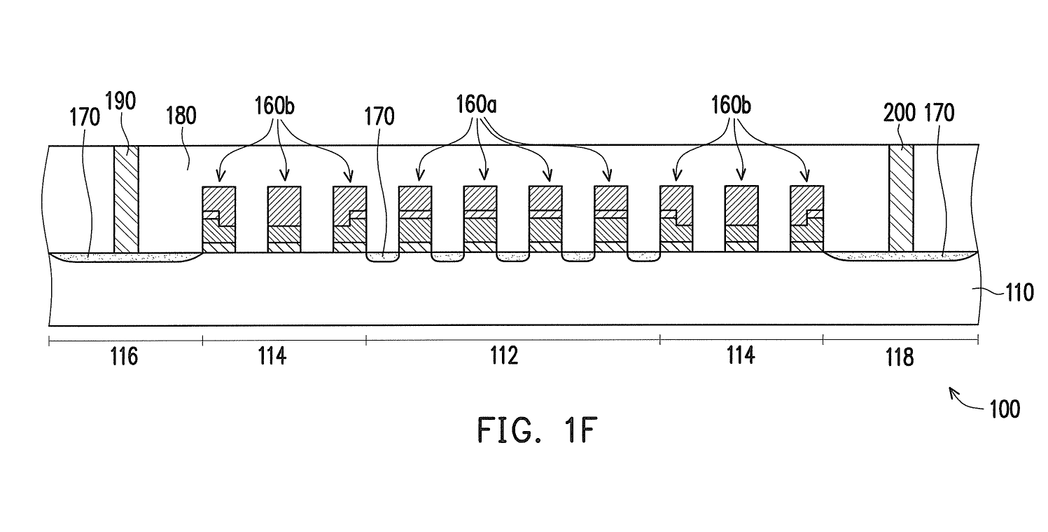

FIGS. 1A to 1F are schematic cross-sectional views illustrating a process of manufacturing a non-volatile memory according to an embodiment of the invention. First, as shown in FIG. 1A, a substrate 110 is provided. The substrate 110 includes a memory cell region 112, two select line regions 114, a source region 116, and a drain region 118, wherein the select line regions 114 are respectively located at two opposite sides of the memory cell region 112. The source region 116 is adjacent to one of the select line regions 114 and located at a side of this select line region 114 that is away from the memory cell region 112. The drain region 118 is adjacent to the other select line region 114 and located at a side of this select line region 114 that is away from the memory cell region 112.

Next, a first dielectric layer 120, a charge storage layer 130, and a second dielectric layer 140 are formed on the substrate 110 in sequence. The first dielectric layer 120 is, for example, an oxide layer. The charge storage layer 130 is, for example, a conductor layer. The second dielectric layer 140 is, for example, an oxide layer. A method for forming the first dielectric layer 120, the charge storage layer 130, and the second dielectric layer 140 are commonly known to persons having ordinary skill in the art and therefore will not be explained in detail hereinafter.

Next, referring to FIG. 1B, the second dielectric layer 140 and a portion of the charge storage layer 130 in the select line region 114 are removed to form an opening 142. A method for forming the opening 142 includes, for example, performing an anisotropic etching process. In this embodiment, the charge storage layer 130 is a conductor layer and may serve with another conductor layer that is to be formed in the subsequent processes as a gate of the select line. Therefore, only the second dielectric layer 140 and a portion of the charge storage layer 130 are removed. Of course, in other embodiments, the second dielectric layer 140 may be the only element that is removed, or the second dielectric layer 140 and the entire charge storage layer 130 underneath the second dielectric layer 140 may be removed.

Thereafter, referring to FIG. 1C, a conductor layer 150 is disposed all over the substrate 110 and fills the opening 142.

It is noted that the charge storage layer 130 is a conductor layer in this embodiment; however, the invention is not limited thereto. In some other embodiments that are not illustrated here, the charge storage layer 130 may also be a nitride layer. In the embodiments that the charge storage layer 130 is a nitride layer, a conductor layer needs to be formed on the first dielectric layer 120 in the select line region 114 later as the gate. Therefore, the opening 142 has to be formed to penetrate the second dielectric layer 140 and the charge storage layer 130 to expose the first dielectric layer 120.

Then, referring to FIG. 1D, a patterning process is performed, so as to pattern the first dielectric layer 120, the charge storage layer 130, the second dielectric layer 140, and the conductor layer 150. Accordingly, a plurality of word lines 160a are defined in the memory cell region 112, and simultaneously a plurality of select lines 160b are defined in the select line regions 114.

In this embodiment, a stack layer (including the first dielectric layer 120, the charge storage layer 130, and the second dielectric layer 140) located in the source region 116 and the drain region 118 is removed when the patterning process defines the word lines 160a and the select lines 160b. To be more specific, a patterned hard mask with a regular pattern is first formed in all the regions (including the memory cell region 112, the select line regions 114, the source region 116, and the drain region 118) by a first exposure, developing and anisotropic etching process. Then, a second exposure, developing and anisotropic etching process are performed to remove the patterned hard mask in the source region 116 and the drain region 118. Afterward, the third anisotropic etching process is executed to remove a portion of the stack layer to form the word lines 160a and the select lines 160b, so as to form the structure shown in FIG. 1D. In this embodiment, the patterned hard mask may be made of silicon nitride, silicon oxide or the other material having etching selectivity which is helpful to form the desired word lines 160a and select lines 160b.

In another embodiment of the invention, at least one stack structure 160s, as shown in FIG. 1D′, which has a line width identical to the line widths of the word lines 160a and the select lines 160b may be simultaneously defined in the source region 116 and the drain region 118 when the patterning process is performed to define the word lines 160a and the select lines 160b. Then, a removing process is performed to remove the stack structure 160s in the source region 116 and the drain region 118, so as to form the structure shown in FIG. 1D. To be more specific, the patterned photoresist with the regular pattern may be first formed in all the regions (including the memory cell region 112, the select line regions 114, the source region 116, and the drain region 118) by the first exposure and developing process. Following that, after a portion of the stack layer is removed by a first anisotropic etching process, the word lines 160a, the select lines 160b, and a plurality of stack structures 160s located in the source region 116 and the drain region 118 are formed. Then, the second exposure and the developing process are performed to remove the photoresist in the source region 116 and the drain region 118, and the anisotropic etching process is performed to remove the stack structures 160s in the source region 116 and the drain region 118, so as to form the structure shown in FIG. 1D.

Referring to FIG. 1C and FIG. 1D, in the word lines 160a, the first dielectric layer 120 serves as a tunneling dielectric layer, the charge storage layer 130 (conductor layer) serves as a floating gate, the second dielectric layer 140 serves as an inter-gate dielectric layer, and the conductor layer 150 serves as a control gate. In the select lines 160b, the first dielectric layer 120 serves as a gate dielectric layer of a select transistor, and the charge storage layer 130 (conductor layer) and the conductor layer 150 together serve as a gate of the select transistor.

Please note that four word lines 160a are illustrated in FIG. 1D as an example. However, the invention is not limited thereto. In other embodiments, the number of the word lines 160a may be 32, 64, 96, or 128, etc., which may be varied by those skilled in the art to meet their needs.

No dummy word line is disposed between the select lines 160b and the word lines 160a, for example. However, in other embodiments, at least one dummy word line may be disposed between the select lines 160b and the word lines 160a.

In this embodiment, a line width L1 of each of the word lines 160a and a line width L2 of each of the select lines 160b are equal to each other. Moreover, a distance S1 between the adjacent word lines 160a, a distance S2 between the adjacent select lines 160b, and a distance S3 between the adjacent select line 160b and word line 160a are equal to one another. In this embodiment, the patterning process is a double patterning process, for example, which easily defines a pattern with equal line widths and equal distances; however, the invention is not limited thereto. Any patterning process that can define equal line widths and equal distances may be used by the invention.

For the conventional non-volatile memory, typically one select line is manufactured in the select line region and the line width of the select line is greater than the line width of the word line. As a result, the pattern is irregular and difficult to form, and the obtained pattern has lower accuracy. In this embodiment, the line widths of the word lines 160a and the select lines 160b are the same, and the distances between the word lines 160a and the select lines 160b are also the same. Therefore, the pattern is regular. For the above reason, the design of the mask used for defining the pattern in the patterning process is simple and an accurate pattern can be obtained without performing an optical proximity correction several times. In addition, because the word lines 160a and the select lines 160b form the regular pattern, the word lines 160a on the edge do not have serious critical dimension variation (CD variation). Line width roughness and line edge roughness of the word lines 160a on the edge are also reduced.

Afterward, referring to FIG. 1E, an ion implantation process is carried out to form a plurality of doped regions 170 in the memory cell region 112, the select line region 114, the source region 116, and the drain region 118. Specifically, the doped regions 170 are formed in the substrate 110 in the memory cell region 112 at two sides of each of the word lines 160a. Moreover, the doped regions 170 are also formed in the substrate 110 located at two sides of the select line regions 114. For example, the doped regions 170 are formed in the substrate 110 outside the two outmost select lines 160b that are located on the edges, as shown in FIG. 1E. In other words, the doped regions 170 are respectively disposed in the substrate 110 at the left side of the select line 160b located on the left and in the substrate 110 at the right side of the select line 160b located on the right. No doped region 170 is formed in the substrate 110 between adjacent select lines 160b. Accordingly, in the select line regions 114, a channel length between the doped regions 170 is maintained the same as the channel length of the single select line with greater line width in the conventional technology and achieves the same effect.

It should be noted that three select lines 160b are foamed in the select line region 114 in this embodiment, but the invention is not limited thereto. In other embodiments, the select line region 114 may include two or four or more select lines 160b. That is, the invention does not limit the number of the select lines 160b in the select line region 114. As long as the channel length between the doped regions 170 meets the requirements, the multiple select lines 160b in the select line region 114 can achieve the same electric properties as the conventional single select line.

In an embodiment (not shown) of the invention, the select line region of the non-volatile memory includes three select lines, wherein the line width of each of the select lines is 28 nm and a width of the select line region is 140 nm. In another embodiment (not shown) of the invention, the select line region of the non-volatile memory includes four select lines, wherein the line width of each of the select lines is 20 nm and the width of the select line region is 140 nm. A comparison example is provided, wherein the select line region of the non-volatile memory includes only one select line. The line width of the select line is 140 nm and the width of the select line region is 140 nm as well.

From another point of view, the select line region 114 of this embodiment includes three select lines 160b with the narrower width, and each of the narrower select lines 160b can independently apply a bias voltage for driving. Therefore, an operation window of the memory is increased. Of course, the select lines 160b with the narrower width may apply a bias voltage together for driving. In other words, multiple narrower equipotential select lines 160b are used in this embodiment in place of the conventional single wider select line, and the line width L2 of each of the select lines 160b is equal to the line width L1 of each of the word lines 160a.

Further, referring to FIG. 1F, a third dielectric layer 180 is formed on the substrate 110. Thereafter, a plurality of source line contacts 190 and a plurality of bit line contacts 200 are respectively formed in the third dielectric layer 180 in the source region 116 and the drain region 118 of the non-volatile memory 100, wherein the source line contacts 190 are hole type contacts, for example. Source lines (not shown) that are to be formed in the subsequent processes will be connected with the doped region 170 of the source region 116 via the source line contacts 190. Bit lines (not shown) that are to be formed in the subsequent processes will be connected with the doped region 170 of the drain region 118 via the bit line contacts 200.

Moreover, this embodiment is illustrated based on the example that multiple holes type source line contacts 190 are formed first and then one source line is formed to connect the hole type source line contacts. Nevertheless, the invention is not limited thereto. In other embodiments, a single line type source line contact may be formed instead to serve as the source line.

It is worth mentioning that the select lines 160b of the non-volatile memory 100 of this embodiment are connected with each other in parallel. Therefore, the select lines 160b may have equal potential, i.e. equipotential driving. However, the select lines 160b of this embodiment may have different potentials, i.e. non-equipotential driving. That is, through the independent driving of the select lines 160b, the potential of each of the select lines 160b may be adjusted to achieve larger operation window of the non-volatile memory 100.

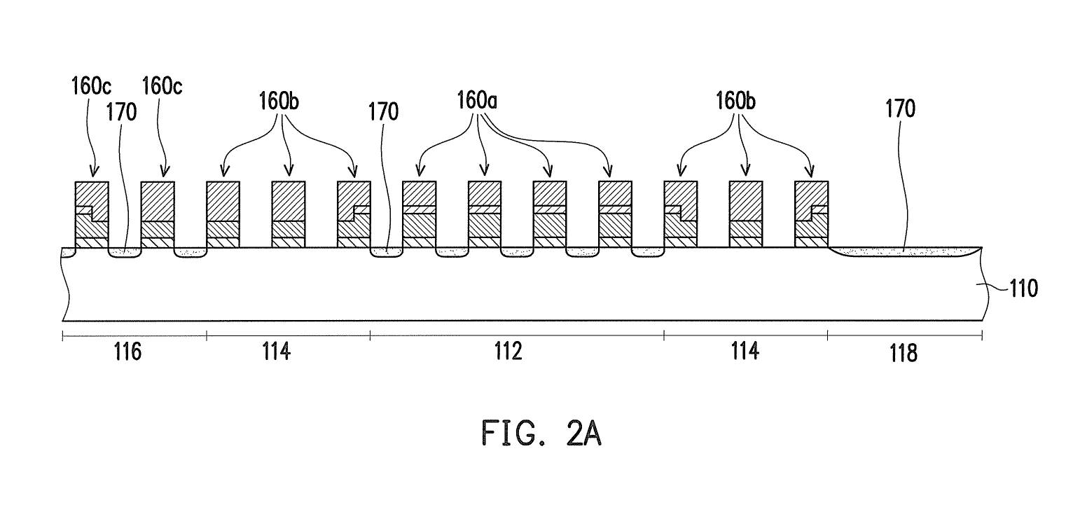

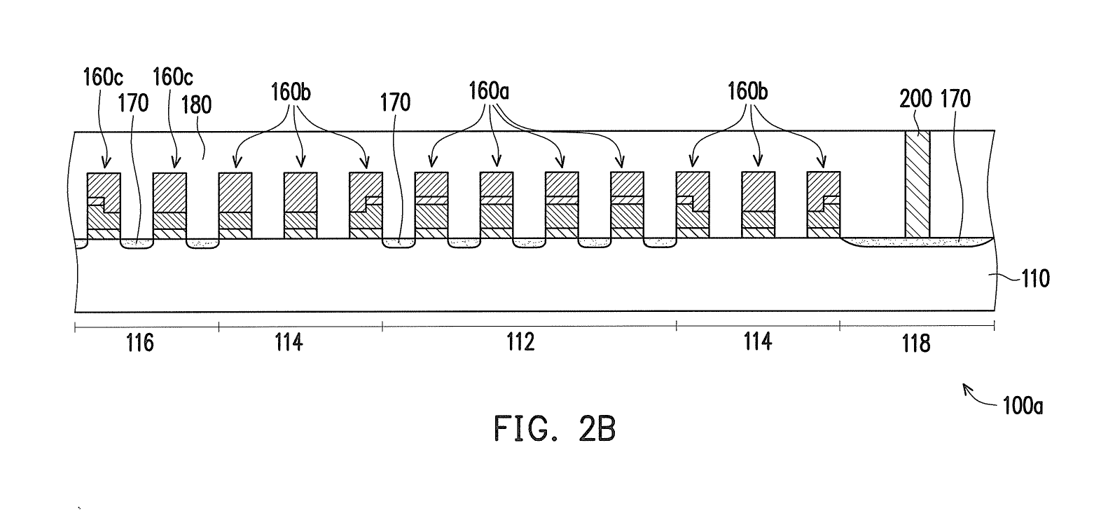

FIGS. 2A to 2B are schematic cross-sectional views illustrating a process of manufacturing a non-volatile memory according to another embodiment of the invention. In this embodiment, elements the same as those of FIGS. 1A to 1F are denoted by the same reference numbers.

First, steps similar to those disclosed in FIGS. 1A to 1D are carried out. The difference between this embodiment and the above embodiment lies in that: in the step of FIG. 1B, the second dielectric layer 140 and a portion of the charge storage layer 130 in the select line region 114 are removed; however, in this embodiment, the second dielectric layer 140 and a portion of the charge storage layer 130 in the source region 116 are also removed.

In addition, in the step of FIG. 1D, at least one stripe-shaped first stack structure 160c (as shown in FIG. 2A) is further defined in the source region 116 when the word lines 160a and the select lines 160b are defined. A line width of the first stack structure 160c may be equal to the line width L1 of the word line 160a and the line width L2 of the select line 160b. Moreover, a distance between the first stack structure 160c and the adjacent select line 160b may be equal to the distance S2 between the adjacent select lines 160b. In this embodiment, the stack layer (including the first dielectric layer 120, the charge storage layer 130, and the second dielectric layer 140) on the drain region 118 is removed when the patterning process defines the word lines 160a and the select lines 160b. To be more specific, a patterned hard mask with a regular pattern is first formed in all the regions (including the memory cell region 112, the select line regions 114, the source region 116, and the drain region 118) by the first exposure, developing and anisotropic etching process. Then, the patterned hard mask located in the drain region 118 is removed by the second exposure, developing and anisotropic etching process. Thereafter, the third anisotropic etching process is performed to remove a portion of the stack layer to form the word lines 160a, the select lines 160b, and the first stack structure 160c, which form the structure shown in FIG. 2A.

In another embodiment of the invention, when the patterning process is performed to define the word lines 160a and the select lines 160b, a plurality of the first stack structures 160c, which respectively have a line width equal to the line widths of the word lines 160a and the select lines 160b, may be defined in the source region 116, and simultaneously a plurality of stack structures (not shown) which respectively have a line width equal to the line widths of the word lines 160a and the select lines 160b may be defined in the drain region 118. Then, the stack structures located in the drain region 118 are removed by the removing process. More specifically, first a patterned photoresist with a regular pattern is formed in all the regions (including the memory cell region 112, the select line regions 114, the source region 116, and the drain region 118) by the first exposure and developing process. Then, after the first anisotropic etching process removes a portion of the stack layer, the word lines 160a, the select lines 160b, the first stack structures 160c, and a plurality of the stack structures in the drain region 118 are formed. Thereafter, the second exposure and developing process are performed to remove the patterned photoresist in the drain region 118, and the second anisotropic etching process is performed to remove the stack structures in the drain region 118 to form the structure as shown in FIG. 2A.

Following that, referring to FIG. 2A again, the ion implantation process is performed to form a plurality of the doped regions 170 in the memory cell region 112, the select line regions 114, the source region 116, and the drain region 118, wherein the doped regions 170 in the memory cell region 112, the select line regions 114, and the drain region 118 are formed in the same positions as illustrated in FIG. 1E. Thus, please refer to the descriptions of FIG. 1E for details. In the source region 116, the doped regions 170 are respectively formed in the substrate 110 at two sides of each of the first stack structures 160c.

Next, referring to FIG. 2B, a step similar to FIG. 1F is performed to foam the third dielectric layer 180 on the substrate 110. Afterward, a source line contact and a source line (not shown) connected with the first stack structures 160c are formed in the third dielectric layer 180 in the source region 116 of a non-volatile memory 100a. The source line contact is connected with the doped regions 170 in the source region 116.

And, a bit line contact 200 is formed in the third dielectric layer 180 in the drain region 118. The first stack structures 160c may serve as a part of the source line. That is to say, when the source line (not shown) is fabricated in the subsequent processes, a source contact may be formed first, and then the source line and the first stack structures 160c are connected via the source line contact, so as to reduce a resistance of the source line.

<Experiment>

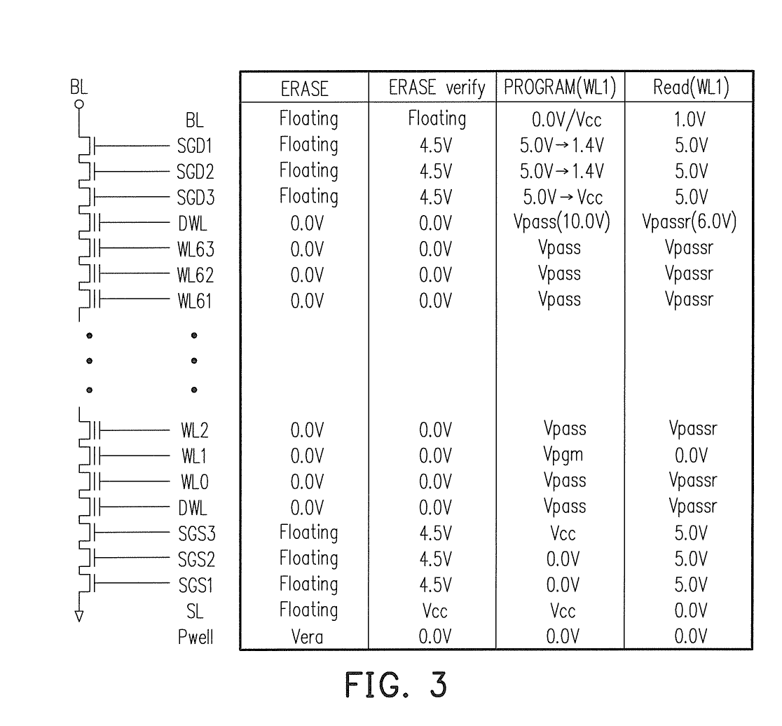

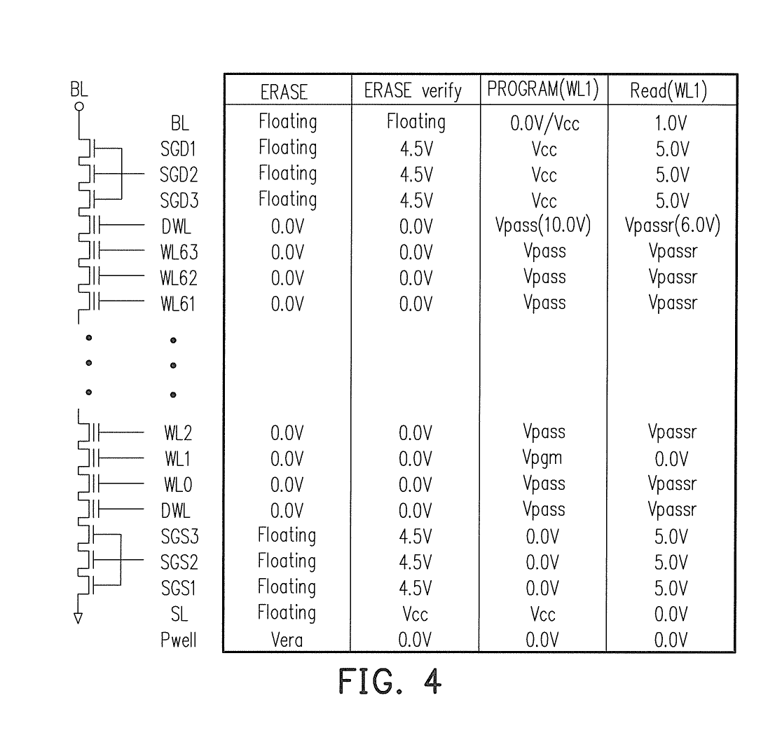

The non-volatile memory of Example 1 includes a plurality of select lines. Each memory cell of the non-volatile memory of Example 1 is connected with one of the word lines. The word lines are denoted as WL0 to WL63. In FIG. 3, SGD1 represents the first select line near the drain region, SGD2 represents the second select line near the drain region and SGD3 represents the third select line near the drain region. SGS1 represents the first select line near the source region, SGS2 represents the second select line near the source region and SGS3 represents the third select line near the source region. BL represents the bit line. SL represents the source line. FIG. 3 and FIG. 4 illustrate operation voltages of an ERASE operation mode, an erase verify operation mode, a PROGRAM operation mode, and a READ operation mode.

FIG. 3 illustrates an operation state when the select lines of the non-volatile memory in Example 1 of the invention are non-equipotential. In the example of FIG. 3, in order to increase an operation window during the operation, SGD1/SGD2/SGD3 may have different potentials, and SGS1/SGS2/SGS3 may also have different potentials.

FIG. 4 illustrates an operation state when the select lines of the non-volatile memory in Example 1 of the invention are equipotential. In the example of FIG. 4, in order not to complicate the circuit design and the operation, SGD1/SGD2/SGD3 may be connected with each other, and SGS1/SGS2/SGS3 may be connected with each other as well. Accordingly, such an operation is the same as the conventional operation that uses only one SGD and one SGS. In addition, it is known from the PROGRAM operation mode of FIG. 4 that the select lines may have equal potentials. Thus, the circuit design and the operation complexity are simplified.

What is claimed is:

1. A manufacturing method of a non-volatile memory, the manufacturing method comprising:
providing a substrate comprising a memory cell region and two select line regions respectively located at two opposite sides of the memory cell region;
forming a first dielectric layer, a charge storage layer, and a second dielectric layer on the substrate in sequence;
at least removing the second dielectric layer in the select line regions;
forming a conductor layer on the substrate;
performing a patterning process to pattern the first dielectric layer, the charge storage layer, the second dielectric layer and the conductor layer to define a plurality of word lines in the memory cell region and a plurality of select lines in the select line regions, wherein a line width of each of the word lines is equal to a line width of each of the select lines; and a distance between the adjacent word lines, a distance between the adjacent select lines and a distance between the adjacent select line and word line are equal to one another; and
forming a plurality of doped regions in the substrate at two sides of each of the word lines and at two sides of each of the select line regions.

2. The manufacturing method according to claim 1, wherein the patterning process comprises a double patterning process.

3. The manufacturing method according to claim 1, wherein the step of at least removing the second dielectric layer in the select line regions comprises removing the second dielectric layer and a portion of the charge storage layer in the select line regions.

4. The manufacturing method according to claim 1, wherein the step of at least removing the second dielectric layer in the select line regions comprises removing the second dielectric layer and the charge storage layer in the select line regions.

5. The manufacturing method according to claim 1, wherein the substrate further comprises a source region and a drain region that are respectively adjacent to the corresponding select line regions, and the manufacturing method further comprises the following:
forming the doped regions in the source region and the drain region; and
forming at least one source line contact in the source region and at least one bit line contact in the drain region, wherein the doped regions are located in the substrate under and at two sides of each of the at least one source line contact and the at least one source line contact is connected with the doped regions in the source region, and the doped regions are located in the substrate under and at two sides of each of the least one bit line contact and the at least one bit line contact is connected with the doped regions in the drain region.

6. The manufacturing method according to claim 1, wherein the substrate further comprises a source region and a drain region that are respectively adjacent to the corresponding select line regions, and the manufacturing method further comprises the following:
forming at least one stack structure respectively in the source region and the drain region when performing the patterning process to define the word lines and the select lines, and a line width of each of the at least one stack structure being equal to the line width of each of the word lines; and
removing the at least one stack structure.

7. The manufacturing method according to claim 6, further comprising the following after removing the at least one stack structure:
forming the doped regions in the source region and the drain region; and
forming at least one source line contact in the source region and at least one bit line contact in the drain region, wherein the doped regions are located in the substrate under and at two sides of each of the at least one source line contact and the at least one source line contact is connected with the doped regions in the source region, and the doped regions are located in the substrate under and at two sides of each of the least one bit line contact and the at least one bit line contact is connected with the doped regions in the drain region.

8. The manufacturing method according to claim 1, wherein the substrate further comprises the source region and the drain region that are respectively adjacent to the corresponding select line regions, and the manufacturing method further comprises the following when performing the patterning process:
defining at least one first stack structure that is stripe-shaped in the source region, wherein a line width of each of the at least one first stack structure is equal to the line width of each of the word lines, and a distance between the adjacent first stack structures, a distance between the adjacent first stack structure and select line, and a distance between the adjacent select lines are equal to one another.

9. The manufacturing method according to claim 8, further comprising the following after the patterning process:
forming the doped regions in the substrate at two sides of each of the at least one first stack structure and forming the doped regions in the drain region; and
forming at least one bit line contact in the drain region, wherein the doped regions are located in the substrate under and at two sides of each of the at least one bit line contact and the at least one bit line contact is connected with the doped regions in the drain region.

10. The manufacturing method according to claim 8, further comprising the following when defining the at least one first stack structure:
defining at least one stack structure in the drain region, wherein a line width of each of the at least one stack structure is equal to the line width of each of the word lines; and
removing the at least one stack structure.

11. The manufacturing method according to claim 10, further comprising the following after removing the at least one stack structure:
forming the doped regions in the substrate at two sides of each of the at least one first stack structure and forming the doped regions in the drain region; and
forming at least one bit line contact in the drain region, wherein the doped regions are located in the substrate under and at two sides of each of the at least one bit line contact and the at least one bit line contact is connected with the doped regions in the drain region.

12. The manufacturing method according to claim 1, wherein the charge storage layer comprises a conductor layer or a nitride layer.

13. A non-volatile memory, comprising:
a substrate comprising a memory cell region and two select line regions respectively located at two opposite sides of the memory cell region;
a plurality of word lines disposed in the memory cell region;
a plurality of select lines disposed in the select line regions, wherein a line width of each of the select lines is equal to a line width of each of the word lines, and a distance between the adjacent select lines, a distance between the adjacent word lines, and a distance between the adjacent select line and word line are equal to one another; and
a plurality of doped regions located in the substrate at two sides of each of the word lines and at two sides of each of the select lines.

14. The non-volatile memory according to claim 13, wherein the substrate further comprises a source region and a drain region, wherein the source region is adjacent to one of the select line regions and located at a side of this select line region that is away from the memory cell region and the drain region is adjacent to the other select line region and located at a side of this select line region that is away from the memory cell region, and the doped regions are further located in the source region and the drain region.

15. The non-volatile memory according to claim 14, further comprising at least one source line contact located in the source region and at least one bit line contact located in the drain region, wherein the doped regions are located in the substrate under and at two sides of each of the at least one source line contact and the at least one source line contact is connected with the doped regions in the source region, and the doped regions are located in the substrate under and at two sides of each of the at least one bit line contact and the at least one bit line contact is connected with the doped regions in the drain region.

16. The non-volatile memory according to claim 14, further comprising at least one first stack structure that is stripe-shaped and located in the source region and at least one bit line contact located in the drain region, wherein the doped regions are located in the substrate at two sides of each of the at least one first stack structure and the doped regions are located in the substrate under and at two sides of each of the at least one bit line contact, and the at least one bit line contact is connected with the doped regions in the drain region.

17. The non-volatile memory according to claim 16, wherein a line width of each of the at least one first stack structure is equal to the line width of each of the word lines.

18. The non-volatile memory according to claim 16, wherein a distance between the adjacent first stack structures, a distance between the adjacent first stack structure and select line, and a distance between the adjacent select lines are equal to one another.

19. The non-volatile memory according to claim 13, wherein the select lines are connected with each other in parallel.
